(19) United States
(12) Patent Application Publication
(10) Pub. No.: US 2025/0069849 A1
(43) Pub. Date: Feb. 27, 2025

(54) DEVICE FOR PERFORMING AN INTERFEROMETRIC MEASUREMENT

(71) Applicant: Technische Universitat Berlin, Berlin (DE)

(72) Inventor: Tolga WAGNER, Berlin (DE)

(73) Assignee: Technische Universitat Berlin, Berlin (DE)

(21) Appl. No.: 18/809,155

(22) Filed: Aug. 19, 2024

(30) Foreign Application Priority Data
Aug. 25, 2023 (EP) 23 193 463.9

(51) Int. Cl. H01J 37/26; H01J 37/147

(52) U.S. Cl. CPC H01J 37/265; H01J 37/147; H01J 2237/24495; H01J 2237/2614

(57) ABSTRACT

Device for performing an interferometric measurement having a source for generating at least two coherent waves, an overlap apparatus for overlapping the at least two coherent waves and for generating an interference pattern, a measuring apparatus for measuring the interference pattern so as to form measured interference values, a disturbance apparatus for disturbing the interference pattern and an analyzer for analyzing the measured interference values, wherein the overlap apparatus comprises a passage region that is delimited at its edge by an edge element and is passed through by the at least two overlapping coherent waves, and comprises a beam-splitting element in the center region of the passage region.

The present application claims the benefit of and priority to European Patent Application EP 23 193 463.9 filed on Aug. 25, 2023. The foregoing application is incorporated by reference herein in its entirety.

The invention relates to a device for performing an interferometric measurement, having a source for generating at least two coherent waves, an overlap apparatus for overlapping the at least two coherent waves and for generating an interference pattern, a measuring apparatus for measuring the interference pattern so as to form measured interference values, a disturbance apparatus for disturbing the interference pattern and an analyzer for analyzing the measured interference values, wherein the overlap apparatus comprises a passage region that is delimited at its edge by an edge element and that is passed through by the at least two overlapping coherent waves, and comprises a beam-splitting element in the center region of the passage region. Such a device is disclosed in European laid-open document EP 3 376 522 A1.

The invention is based on the object of further developing a device of the described type with regard to a particularly efficient possibility of influencing the waves and the interference pattern.

According to the invention, this object is achieved by a device having the features as claimed in claim 1.

Advantageous embodiments of the device according to the invention are given in dependent claims.

Provision is accordingly made, according to the invention, for the edge element to have an electrically conductive cladding section having a through-hole the inner wall of which is electrically isolated from a control electrode, located in the through-hole, of the edge element by an insulator, and for the disturbance apparatus to be electrically connected to the control electrode and suitable for applying a voltage between the cladding section and the control electrode in order to disturb the interference.

One essential advantage of the device according to the invention is that the proposed edge-side driving of the edge element allows the interference to be influenced much more efficiently than in the case of the central driving of the beam-splitting element described in the cited laid-open document.

Another essential advantage of the device according to the invention is that the control electrode guided in the through-hole of the cladding section makes it possible to feed in radio waves or microwaves with a high amplitude and low losses, thereby making it possible to achieve a particularly high phase deviation in the interference pattern shift.

The device is preferably an electron holography measuring apparatus. Accordingly, the source is preferably an electron source, and the coherent waves are electron waves.

It is advantageous, in particular for symmetry reasons, for the center axis of the through-hole (and thus the center axis of the control electrode) to extend in the direction of the beam-splitting element and for an imaginary connecting line between an electrode end, facing the passage region, of the control electrode and a section, closest thereto, of the beam-splitting element to be located on the center axis.

An end section, adjoining the passage region, of the through-hole is preferably insulator-free. An insulator-free end section supports the formation of a pronounced interference-disturbing field in the passage region adjoining the edge element.

The length of the insulator-free end section is preferably between 0.75 times and 1.25 times the diameter of the control electrode.

An electrode end, facing the passage region, of the control electrode is preferably located inside the through-hole (that is to say offset inwardly in the cladding section) and preferably has a spacing from the outer surface, delimiting the passage region, of the cladding section.

The spacing between the electrode end and the outer surface of the cladding section is preferably between 0.5 times and 1.0 times the diameter of the control electrode.

It is considered to be particularly advantageous for the control electrode to have an end region that tapers in the direction of the passage region. Tapering of the end region makes it possible to control the spatial field distribution of the interference-disturbing field and thus to optimize same with regard to the disturbance effect on the passage region.

The length of the tapering end region—seen along the longitudinal axis of the through-hole—is preferably less than half the diameter of the control electrode.

The end region is preferably rotationally symmetrical.

With regard to the tapering of the end region, it is considered advantageous for this to taper conically. It is advantageous for example for the end region to be circular-conical or circular-frustoconical.

In another advantageous embodiment, provision is made for the outer surface of the end region to be curved radially inwardly, for example radially inwardly in the direction of an axis of rotation. The curvature makes it very easy to adapt the shape of the electric field to the respective requirements.

The curvature radius of the curvature is preferably smaller than the diameter of the control electrode.

An additional edge element is preferably located opposite the edge element; the beam-splitting element is preferably arranged between the edge element and the additional edge element, for example centrally and symmetrically with respect to the center axis of the control electrode.

The outer diameter of the cladding section of the edge element and the outer diameter of the additional edge element are preferably the same size.

The additional edge element is preferably at the same electrical potential as the cladding section of the edge element.

The invention furthermore relates to an overlap apparatus comprising a passage region that is delimited at its edge by an edge element and comprising a beam-splitting element in the center region of the passage region. Such an overlap apparatus is known from the laid-open document cited at the outset.

According to the invention, with regard to the overlap apparatus, provision is made for the edge element to have an electrically conductive cladding section having a through-hole the inner wall of which is electrically isolated from a control electrode, located in the through-hole, of the edge element by an insulator, and for the control electrode to have a terminal to which an electrical potential is able to be applied in order to disturb an interference, said electrical potential differing from the electrical potential at the cladding section.

With regard to the advantages of the overlap apparatus according to the invention and advantageous embodiments of the overlap apparatus according to the invention, the above explanations given in connection with the device according to the invention apply accordingly. This means for example that the design of the edge element and that of the additional edge element, along with the arrangement of the edge element and additional edge element, may be selected as explained above in connection with the device according to the invention and below in connection with the description of the figures.

The overlap apparatus is preferably aperture holder-compatible, that is to say designed to be inserted into an aperture holder of an electron microscope or an electron holography measuring apparatus.

The invention will be explained in more detail below with reference to exemplary embodiments, in which, by way of example:

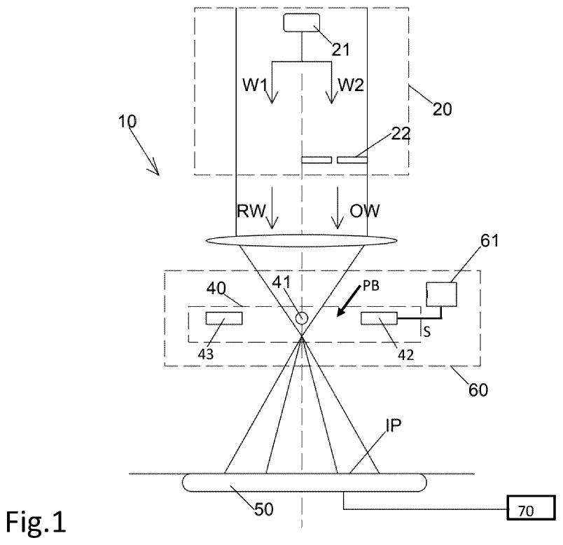

FIG. 1 shows one exemplary embodiment of an arrangement according to the invention equipped with one exemplary embodiment of an overlap apparatus according to the invention, this exemplary embodiment of an overlap apparatus having an edge element,

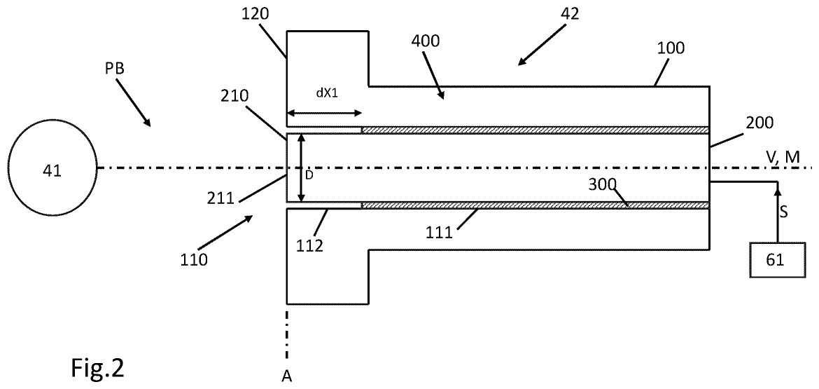

FIG. 2 shows, in more detail, a first exemplary embodiment of the edge element of the arrangement according to FIG. 1, wherein a control electrode of the edge element has a planar end surface,

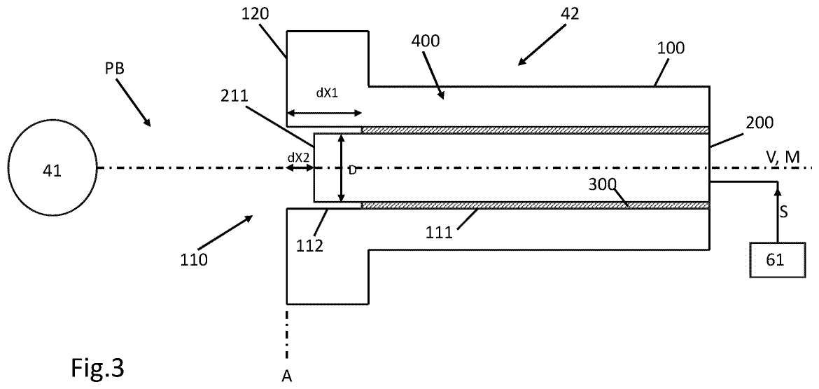

FIG. 3 shows, in more detail, a second exemplary embodiment of the edge element of the arrangement according to FIG. 1, wherein a control electrode of the edge element has an electrode tip at the end of a conical end region of the control electrode,

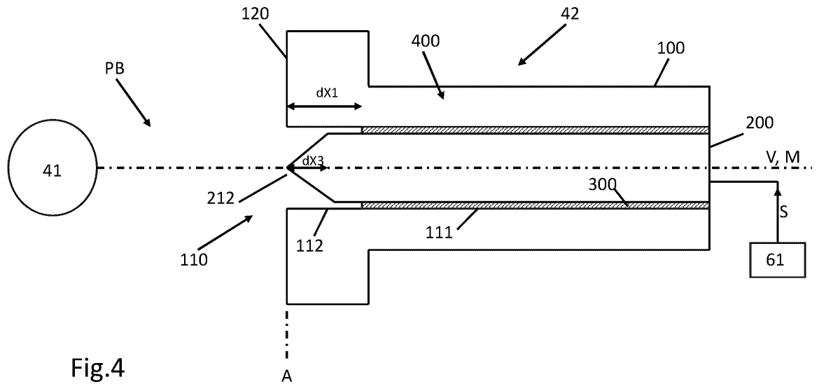

FIG. 4 shows, in more detail, a third exemplary embodiment of the edge element of the arrangement according to FIG. 1, wherein a control electrode of the edge element has an electrode tip at the end of a conical end region,

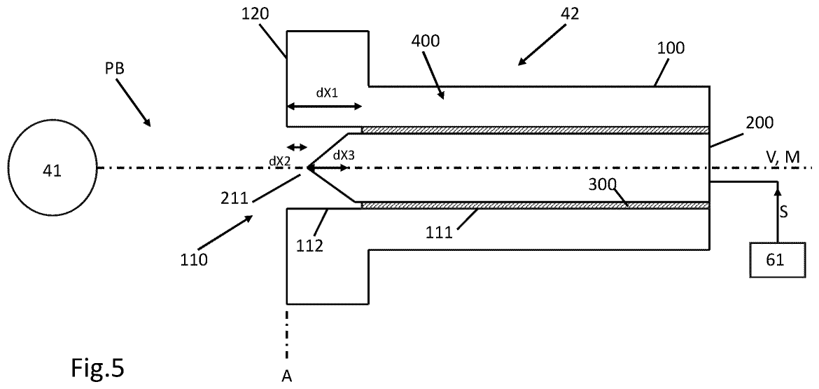

FIG. 5 shows, in more detail, a fourth exemplary embodiment of the edge element of the arrangement according to FIG. 1, wherein a control electrode of the edge element has an inwardly offset electrode tip at the end of a conical end region,

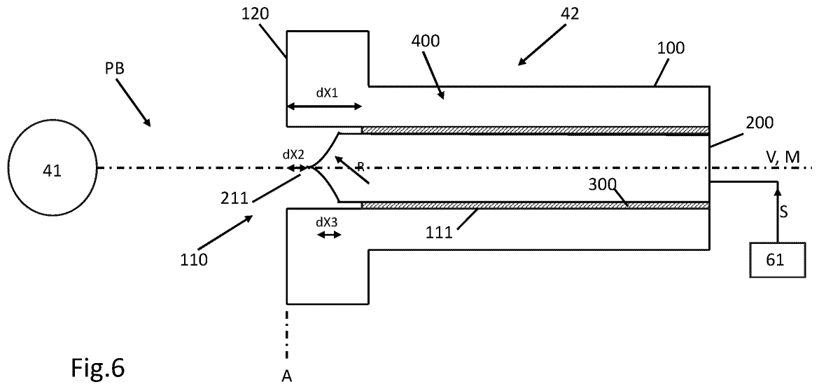

FIG. 6 shows, in more detail, a fifth exemplary embodiment of the edge element of the arrangement according to FIG. 1, wherein a control electrode of the edge element has an inwardly offset electrode tip at the end of a radially inwardly curved end region, and

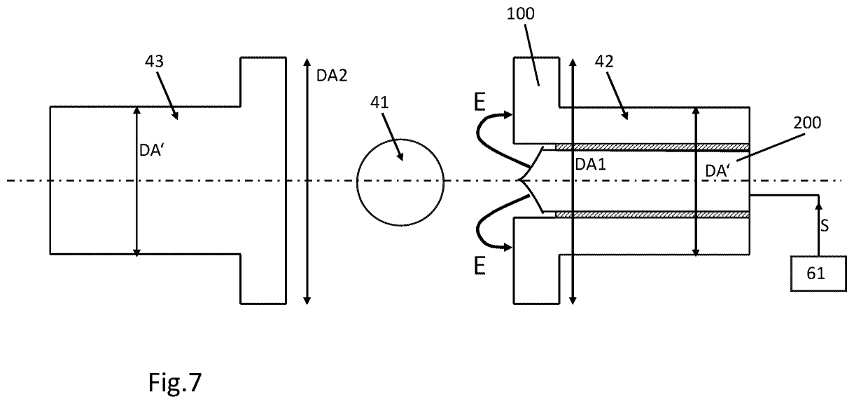

FIG. 7 shows, with reference to the fifth exemplary embodiment according to FIG. 6, one preferred exemplary embodiment of an overlap apparatus according to the invention suitable for the arrangement according to FIG. 1.

For the sake of clarity, the same reference signs are always used in the figures for identical or comparable components.

FIG. 1 shows one exemplary embodiment of a device 10 suitable for time-resolved interferometric measurements. The device 10 may form or be contained in an electron holography system.

The device 10 comprises a source 20 for generating two coherent electron waves, referred to hereinafter as reference wave RW and object wave OW. For this purpose, the source 20 has an electron emitter 21 that emits a first partial electron wave W1 and a second partial electron wave W2. The first partial electron wave W1 is preferably transmitted by vacuum and forms the reference wave RW. The second partial electron wave W2, which is coherent with the first partial electron wave W1, passes through an object 22 and forms the object wave OW.

The reference wave RW and the object wave OW pass through a lens 30 and an overlap apparatus 40. The overlap apparatus 40 overlaps the reference wave RW and the object wave OW and generates an interference pattern IP, which is measured by a measuring apparatus 50 and evaluated by an analyzer 70.

In the exemplary embodiment according to FIG. 1, the overlap apparatus 40 comprises a passage region PB through which the overlapping coherent waves pass. The passage region PB is divided into two sections by a beam-splitting element 41 in the center region of the passage region PB.

In FIG. 1, the passage region PB is delimited at its edge, on the right-hand edge, by an edge element 42 that is equipped with a control electrode, which is not shown for the sake of clarity. The control electrode is connected to a disturbance apparatus 61 and may have an electrical control or disturbance signal S applied to it by said disturbance apparatus. The control electrode is arranged inside a cladding section of the edge element 42.

The disturbance unit formed from the disturbance apparatus 61 and the overlap apparatus 40 is identified by reference sign 60 in FIG. 1.

An additional edge element 43 is located opposite the edge element 42 and delimits the passage region PB at its edge on the left-hand side of FIG. 1.

The beam-splitting element 41, a cladding section of the edge element 42 and the additional edge element 43 are electrically conductive and are preferably at the same electrical potential, for example ground potential. As an alternative, the beam-splitting element 41, the cladding section of the edge element 42 and the additional edge element 43 may be at different potentials.

In the exemplary embodiment according to FIG. 1, the edge element 42, able to be driven or controlled by the disturbance apparatus 61, primarily influences the object wave OW, because this passes through the region between the edge element 42 and the beam-splitting element 41, whereas the reference wave RW passes through the region between the opposite edge element 43 and the beam-splitting element 41. As an alternative, the arrangement of the edge element 42 and of the opposite edge element 43 may also be swapped: In such a case, the edge element 42, able to be driven by the disturbance apparatus 61, would primarily influence the reference wave RW, because this would pass through the region between the edge element 42 and the beam-splitting element 41, whereas the object wave OW would pass through the region between the opposite edge element 43 and the beam-splitting element 41.

Moreover, it is additionally also possible to design the opposite edge element 43 to be driveable, for example to be driveable in exactly the same way as the edge element 42, in order to make it possible to influence both waves, that is to say the object wave OW and the reference wave RW. In the latter case, it is advantageous for the opposite edge element 43 to be connected to its own disturbance apparatus, which is not shown in FIG. 1 and generates a further control signal different from the control signal S of the disturbance apparatus 61.

FIG. 2 shows a first exemplary embodiment of an edge element 42, which may be used as the edge element 42 in the arrangement according to FIG. 1, in more detail.

It may be seen that an electrically conductive, flange-shaped cladding section 100 of the edge element 42 is equipped with a through-hole 110 the inner wall 111 of which is electrically isolated from the control electrode 200 located in the through-hole 110 by an electrical insulator 300. The control electrode 200 and the cladding section 100, which is electrically isolated therefrom, together form an electric coaxial conductor 400 that, due to its dimensioning, is suitable for transmitting high-frequency electrical signals, such as for example those in the radio wave or microwave frequency range, that is to say for frequencies between 5 kHz and 50 GHz.

The following dimensions and properties of the edge element 42 are considered to be advantageous for the transmission of signals for high-frequency electrical signals in the radio wave or microwave frequency range:

$$µm < D < 1000 µm$$

10 μm<thickness of the insulator layer <500 μm
material of the insulator 300: polyethylene or polytetrafluoroethylene
material of the control electrode 200: gold-plated copper
material of the cladding section 100: stainless steel (non-magnetic)

The disturbance apparatus 61 is thus able, in order to disturb the interference of the electron waves, to feed in a high-frequency electrical control signal S in the radio wave or microwave range via the coaxial conductor 400 and to generate a high-frequency alternating electric field in the region of the end section 112, adjoining the passage region PB, of the through-hole 110, said high-frequency alternating electric field making it possible to disturb the interference of the electron waves at a correspondingly high frequency. The voltage generated by the disturbance apparatus 61 and transmitted via the coaxial conductor 400 is preferably an AC voltage in the frequency range between 10 kHz and 1 GHz.

The disturbance apparatus 61 may for example be a noise generator that generates a high-frequency noise signal as control signal S.

In the exemplary embodiment according to FIG. 2, the center axis M of the through-hole 110, and thus that of the control electrode 200, extends in the direction of the beam-splitting element 41. An imaginary connecting line V between the electrode end 210, facing the passage region PB, of the control electrode 200 and the section, closest thereto, of the beam-splitting element 41 is preferably located on the center axis M.

In order to support the efficient formation of a disturbance field that disturbs the interference, in the exemplary embodiment according to FIG. 2, the end section 112, adjoining the passage region PB, of the through-hole 110 is insulator-free. The length dX1 of the insulator-free end section 112 is preferably between 0.75 times and 1.25 times the diameter D of the control electrode 200:

$$0.75 ⋆ D < d X 1 < 1.25 ⋆ D .$$

In the exemplary embodiment according to FIG. 2, the electrode end 210, facing the passage region PB, of the control electrode 200 is planar and has a planar end surface 211 that is arranged perpendicular to the center axis M and is located in the same plane, here the plane A of the outer surface 120 of the cladding section 100, as the outer surface 120, delimiting the passage region PB, of the cladding section 100.

FIG. 3 shows a second exemplary embodiment of an edge element 42, which may be used as the edge element 42 in the arrangement according to FIG. 1.

In the second exemplary embodiment according to FIG. 3, the electrode end 210, facing the passage region PB, of the control electrode 200 is likewise planar and likewise has a planar end surface 211 that is arranged perpendicular to the center axis M; in this respect, the first and second exemplary embodiment correspond to one another.

Unlike in the first exemplary embodiment according to FIG. 2, in the second exemplary embodiment according to FIG. 3, the electrode end 210, facing the passage region PB, of the control electrode 200 is arranged inside the through-hole 110, that is to say offset inwardly, and is thus not in the same plane as the outer surface 120, delimiting the passage region PB, of the cladding section 100.

With a view to particularly efficient formation of the disturbance field, the electrode end 210 has a spacing dX2 from the outer surface 120, adjoining the passage region PB, of the cladding section 100; the spacing dX2 is preferably between 0.5 times and 1.0 times the diameter of the control electrode 200:

$$0.5 ⋆ D < dX 2 < D .$$

With regard to the length of the insulator-free cladding section 100 or the length dX1 of the insulator-free end section 112 of the through-hole 110, the following applies preferably again:

$$0.75 ⋆ D < dX 1 < 1.25 ⋆ D .$$

FIG. 4 shows a third exemplary embodiment of an edge element 42, which may be used as the edge element 42 in the arrangement according to FIG. 1, in more detail.

The third exemplary embodiment differs from the first and second exemplary embodiment in that the electrode end 210, facing the passage region PB, of the control electrode 200 is not planar, but is formed by an electrode tip 212. The end region of the control electrode 200 is circular-conical or circular-frustoconical and rotationally symmetrical with respect to the center axis M.

The length dX3 of the tapering end region—seen along the center axis M of the through-hole 110—is less than half the diameter D of the control electrode 200:

$$dX 3 < D / 2.$$

With regard to the length of the insulator-free cladding section 100 or the length dX1 of the insulator-free end section of the through-hole 110, the following applies preferably again:

$$0.75 ⋆ D < dX 1 < 1.25 * D .$$

In the third exemplary embodiment according to FIG. 4, the electrode tip 212, facing the passage region PB, of the control electrode 200 is in the same plane A as the outer surface 120, delimiting the passage region PB, of the cladding section 100.

FIG. 5 shows a fourth exemplary embodiment of an edge element 42, which may be used as the edge element 42 in the arrangement according to FIG. 1.

In the fourth exemplary embodiment according to FIG. 5, the end region, facing the passage region PB, of the control electrode 200 likewise tapers to a tip so as to form an electrode tip 212; in this respect, the third and fourth exemplary embodiment correspond to one another.

Unlike in the third exemplary embodiment according to FIG. 4, in the fourth exemplary embodiment according to FIG. 5, the electrode tip 212, facing the passage region PB, of the control electrode 200 is arranged inside the through-hole 110, and is thus not in the same plane as the outer surface 120, delimiting the passage region PB, of the cladding section 100.

With a view to particularly efficient formation of the disturbance field, the electrode tip 212 has a spacing dX2 from the outer surface 120, adjoining the passage region PB, of the cladding section 100; the spacing dX2 is preferably between 0.5 times and 1.0 times the diameter of the control electrode 200:

$$0.5 ⋆ D < dX 2 < D .$$

With regard to the length of the insulator-free cladding section 100 or the length dX1 of the insulator-free end section of the through-hole 110, the following applies preferably again:

$$0.75 ⋆ D < dX 1 < 1.25 ⋆ D .$$

FIG. 6 shows a fifth exemplary embodiment of an edge element 42, which may be used as the edge element 42 in the arrangement according to FIG. 1.

The fifth exemplary embodiment likewise has an electrode tip 212, but differs from the third and fourth exemplary embodiment in that the end region, facing the passage region PB, of the control electrode 200 is not circular-conical or circular-frustoconical, but rather has an outer surface that is curved radially inwardly in the direction of the center axis M forming an axis of rotation. The curvature radius R of the curvature is preferably smaller than the diameter D of the control electrode 200:

$$0 < R < D$$

The length dX3 of the tapering end region of the control electrode 200—seen along the longitudinal or center axis M of the through-hole 110—is preferably less than half the diameter D of the control electrode 200:

$$dX 3 < D / 2.$$

With regard to the length of the insulator-free cladding section 100 or the length dX1 of the insulator-free through-hole 110, the following applies preferably again:

$$0.75 ⋆ D < dX 1 < 1.25 ⋆ D .$$

The cladding sections 100 of the edge element 42 are preferably flange-shaped, as shown by way of example in FIGS. 2 to 5.

FIG. 7 shows one exemplary embodiment of an overlap apparatus 40 according to the invention, which may be used in the arrangement according to FIG. 1.

The overlap apparatus 40 according to FIG. 7 comprises an edge element 42, for example the edge element 42 according to FIG. 6, the additional edge element 43 shown in FIG. 1 and the beam-splitting element 41 shown in FIG. 1.

Instead of the edge element 42 shown in FIG. 7, according to FIG. 6, the overlap apparatus 40 may also have a differently designed edge element, such as for example one of the edge elements 42 according to FIGS. 2 to 5.

For symmetry reasons, it is advantageous for the outer diameter DA1 of the cladding section 100 of the edge element 42 to be the same size as the outer diameter DA2 of the additional edge element 43, as shown in more detail in FIG. 7 with reference to the example of the edge element 42 according to FIG. 6.

For symmetry reasons, it is also advantageous for the additional edge element 43 likewise to be of flange-shaped design, that is to say the outer shape of the additional edge element 43 and the outer shape of the cladding section 100 of the edge element 42 are shaped and dimensioned identically.

It is advantageous for the following relationship to apply for the outer diameter DA′ of the edge element 42 in the center region, adjoining the flange region, of the edge element 42:

$${DA}^{′} < DA 1 / 2.$$

The same applies for the outer diameter DA′ of the additional edge element 43 in the center region adjoining the flange region.

FIG. 7 also shows, in highly simplified form and only schematically, two field lines of the electric field, which may be brought about between the control electrode 200 and the cladding section 100 of the edge element 42 by the disturbance signal S in order to disturb the interference of the electron waves—by way of illustration, by shifting the electron beams by attracting or repelling the electrons of the electron beams.

Similar electric fields also arise between the control electrode 200 and the cladding section 100 of the edge element 42 in the exemplary embodiments according to FIGS. 2 to 5 as soon as a voltage is applied between the control electrode 200 and the cladding section 100.

Finally, it should be mentioned that the features of all of the exemplary embodiments described above may be combined with one another as desired to form further, additional exemplary embodiments of the invention.

Also, all of the features of dependent claims may each be combined individually with each of the coordinate claims, each on their own or in any combination with one or more other dependent claims, in order to obtain further, additional exemplary embodiments.

### LIST OF REFERENCE SIGNS

10 Device
20 Source
21 Electron emitter
22 Object
30 Lens
40 Overlap apparatus
41 Beam-splitting element
42 Edge element
43 Additional edge element
50 Measuring apparatus
60 Disturbance unit
61 Disturbance apparatus
70 Analyzer
100 Cladding section
110 Through-hole
111 Inner wall
112 End section
120 Outer surface
200 Control electrode
210 Electrode end
211 Planar end surface
212 Electrode tip
300 Insulator
400 Coaxial conductor
A Plane
dx1 Length
dx2 Spacing
dx3 Length
D Diameter
DA1 Outer diameter
DA2 Outer diameter
DA′ Outer diameter
IP Interference pattern
M Center axis
OW Object wave
PB Passage region
R Curvature radius
RW Reference wave
S Electrical control signal
V Connecting line
W1 First partial electron wave
W2 Second partial electron wave

1. A device (10) for performing an interferometric measurement, having
a source (20) for generating at least two coherent waves (OW, RW),
an overlap apparatus (40) for overlapping the at least two coherent waves (OW, RW) and for generating an interference pattern (IP),
a measuring apparatus (50) for measuring the interference pattern (IP) so as to form measured interference values (I(x,y)),
a disturbance apparatus (61) for disturbing the interference pattern (IP) and
an analyzer (70) for analyzing the measured interference values (I(x,y)),
wherein the overlap apparatus (40) comprises a passage region (PB) that is delimited at its edge by an edge element (42) and is passed through by the at least two overlapping coherent waves, and comprises a beam-splitting element (41) in the center region of the passage region (PB),
wherein
the edge element (42) has an electrically conductive cladding section (100) having a through-hole (110) the inner wall (112) of which is electrically isolated from a control electrode (200), located in the through-hole (110), of the edge element (42) by an insulator (300), and
the disturbance apparatus (61) is electrically connected to the control electrode (200) and suitable for applying a voltage between the cladding section (100) and the control electrode (200) in order to disturb the interference.

2. The device as claimed in claim 1, wherein the center axis (M) of the through-hole (110) extends in the direction of the beam-splitting element (41) and an imaginary connecting line (V) between an electrode end (210), facing the passage region (PB), of the control electrode (200) and a section, closest thereto, of the beam-splitting element (41) is located on the center axis (M).

3. The device as claimed in claim 1, wherein
an end section, adjoining the passage region (PB), of the through-hole (110) is insulator-free and
the length (dX1) of the insulator-free end section is between 0.75 times and 1.25 times the diameter (D) of the control electrode (200).

4. The device as claimed in claim 1, wherein an electrode end (210), facing the passage region (PB), of the control electrode (200) is located inside the through-hole (110) and has a spacing from the outer surface (120), delimiting the passage region (PB), of the cladding section (100).

5. The device as claimed in claim 4, wherein the spacing (dX2) between the electrode end (210) and the outer surface (120) of the cladding section (100) is between 0.5 times and 1.0 times the diameter (D) of the control electrode (200).

6. The device as claimed in claim 1, wherein the control electrode (200) has an end region that tapers in the direction of the passage region (PB).

7. The device as claimed in claim 6, wherein the length (dX3) of the tapering end region, seen along the longitudinal axis of the through-hole (110), is less than half the diameter (D) of the control electrode (200).

8. The device as claimed in claim 6, wherein the end region is rotationally symmetrical and/or tapers conically.

9. The device as claimed in claim 6, wherein the end region is circular-conical or circular-frustoconical.

10. The device as claimed in claim 6, wherein the outer surface of the end region is curved radially inwardly in the direction of an axis of rotation.

11. The device as claimed in claim 10, wherein the curvature radius (R) of the curvature is smaller than the diameter (D) of the control electrode (200).

12. The device as claimed in claim 1, wherein an additional edge element (43) is located opposite the edge element (42) and the beam-splitting element (41) is arranged between the edge element (42) and the additional edge element (43).

13. The device as claimed in claim 1, wherein the device is an electron holography measuring apparatus and the source is an electron beam source.

14. An overlap apparatus for the device of claim 1, wherein the overlap apparatus (40) comprises a passage region (PB) that is delimited at its edge by an edge element (42) and is able to be passed through by overlapping coherent waves, and comprises a beam-splitting element (41) in the center region of the passage region (PB),
wherein
the edge element (42) has an electrically conductive cladding section (100) having a through-hole (110) the inner wall (112) of which is electrically isolated from a control electrode (200), located in the through-hole (110), of the edge element (42) by an insulator (300), and
the control electrode (200) has a terminal to which an electrical potential is able to be applied in order to disturb an interference, said electrical potential differing from the electrical potential at the cladding section (100).

15. The overlap apparatus as claimed in claim 14, wherein
an additional edge element (43) is located opposite the edge element (42) and a beam-splitting element (41) is arranged between the edge element (42) and the additional edge element (43), and
the overlap apparatus is dimensioned and designed to be inserted into an aperture holder of an electron holography measuring apparatus or an electron beam microscope.
